(19) United States
(12) Patent Application Publication
(10) Pub. No.: US 2015/0140726 A1
(43) Pub. Date: May 21, 2015

(54) METHOD FOR MANUFACTURING SEMICONDUCTOR DEVICE

(71) Applicant: SHARP KABUSHIKI KAISHA, Osaka-shi, Osaka (JP)

(72) Inventors: Shinya Honda, Osaka-shi (JP); Yoshiyuki Nasuno, Osaka-shi (JP); Kazuhito Nishimura, Osaka-shi (JP); Atsushi Tomyo, Osaka-shi (JP); Takashi Yamada, Osaka-shi (JP)

(21) Appl. No.: 14/413,304

(22) PCT Filed: May 21, 2013
(86) PCT No.: PCT/JP2013/064100

§ 371 Date: Jan. 7, 2015

(30) Foreign Application Priority Data
Jul. 10, 2012 (JP) 2012-154324

(51) Int. Cl. H01L 31/18; H01L 31/0224

(52) U.S. Cl. CPC H01L 31/1884; H01L 31/022466; H01L 31/186
USPC 438/98

(57) ABSTRACT

A transparent conductive substrate (1) in which a transparent conductive film (12) is placed on a light-transmissive base plate (11) is brought into a reaction chamber of a plasma apparatus without being rinsed (Step (a)) and the transparent conductive film (12) is treated with plasma using a CH₄ gas and an H₂ gas (Step (b)). After Step (b), semiconductor devices are deposited on the transparent conductive film (12) in series (Steps (c) and (d)) and a semiconductor device (10) is manufactured (Step (e)).

### TECHNICAL FIELD

This invention relates to a method for manufacturing a semiconductor device.

### BACKGROUND ART

Thin-film transistors or thin-film solar cells are fabricated on a transparent conductive film formed on a glass substrate. In usual, in the case of forming the above semiconductor devices on the transparent conductive film on the glass substrate, a rinsing step of removing pollutants on the transparent conductive film is performed by pure water rinsing in order to avoid influences on semiconductor device properties.

Hitherto, in the case of transporting substrates from a transparent conductive substrate maker to a semiconductor device factory, a plurality of transparent conductive substrates have been handled in a stacked state and slip sheets, similar to glass sheet packages, for glass have been used to avoid defects such as surface flaws. As the quality of semiconductor devices has been enhanced, requirements for the quality of the transparent conductive substrates have become severe and requirements for the quality of the slip sheets used have also become severe. The slip sheets used contain resin and therefore glass surfaces and transparent conductive film surfaces in contact with the slip sheets are readily contaminated due to the adhesion of organic substances and the like. Therefore, before semiconductor devices are fabricated on a transparent conductive film, surfaces of a substrate are cleaned in a rinsing step.

However, in recent years, for semiconductor devices typified by photoelectric converters, substrates have been upsized and therefore rinsing systems and drying systems have needed to be upsized. The increase in running cost of a rinsing step and the increase in time of a rinsing/drying step lead to the increase in manufacturing cost of a semiconductor device. If a surface of a transparent conductive film is not sufficiently rinsed, then a semiconductor device is formed on the surface of the transparent conductive film that has organic substances adhering thereto. This leads to a reduction in adhesion to cause a problem in that film peeling is likely to occur after the deposition of a photoelectric conversion layer. As for a manufacturing line in an environment with low cleanliness, there is a problem in that a transparent conductive substrate cleaned in a rinsing step is re-contaminated with atmospheric components during the transportation of the transparent conductive substrate into a manufacturing system or during waiting for transportation. In consideration of the re-contamination of the transparent conductive substrate, a step of cleaning the transparent conductive substrate is preferably performed immediately before a step of depositing a semiconductor device.
Patent Literature 1: Japanese Patent No. 2521815
Patent Literature 2: Japanese Patent No. 2674031
Patent Literature 3: Japanese Unexamined Patent Application Publication No. 2009-231246
Patent Literature 4: Japanese Unexamined Patent Application Publication No. 2009-211888
Patent Literature 5: Japanese Unexamined Patent Application Publication No. 2010-3872
Patent Literature 6: Japanese Unexamined Patent Application Publication No. 7-101483
Non-patent Literature 1: J. H Thomas III, Appl. Phys. Lett 42, 1983, p 794.

### DISCLOSURE OF INVENTION

Physical etching performed by sputtering for the purpose of cleaning surfaces of a transparent conductive substrate is not preferred in semiconductor device steps because there is a problem with contamination in manufacturing systems and transparent conductive films may possibly be damaged by sputtering. Tin oxide or indium tin oxide used as a transparent conductive film for photoelectric conversion layers is known to be readily reduced by hydrogen radicals during the deposition of a photoelectric conversion layer. Tin oxide or indium tin oxide is not cleaned by hydrogen plasma treatment (Non-patent Literature 1). Etching is known to be performed for the purpose of patterning tin oxide or indium tin oxide by reactive dry etching using a hydrocarbon (Patent Literature 1).

However, Patent Literature 1 describes only an etching technique for patterning a transparent conductive film and does not disclose properties of the etched transparent conductive film, properties of a semiconductor device including the transparent conductive film, or an increase in reliability.

The present invention provides a method for manufacturing a semiconductor device, the method being capable of preventing the increase of manufacturing cost by rinsing a surface of a transparent conductive film by an inexpensive method and being capable of enhancing the reliability and properties of a semiconductor device formed thereon.

According to an embodiment of this invention, a method for manufacturing a photoelectric converter includes a first step in which in a transparent conductive substrate in which a transparent conductive film mainly containing tin oxide or indium oxide is placed on a light-transmissive base plate, a surface of the transparent conductive film is plasma-treated using a CH₄ gas and an H₂ gas and a second step of fabricating a semiconductor device on the transparent conductive film after the first step.

According to an embodiment of this invention, a surface of a transparent conductive film of a transparent conductive substrate is plasma-treated using a CH₄ gas and an H₂ gas and reduction and etching are performed at once, whereby the transmittance of the transparent conductive film is maintained, no carbon film is deposited, impurities on a surface of the transparent conductive film are removed by etching the transparent conductive film, and a surface of the transparent conductive film can be cleaned immediately before a semiconductor device is formed. As a result, the interface between the transparent conductive film and the semiconductor device is formed well and the reliability and properties of the semiconductor device can be enhanced.

### BRIEF DESCRIPTION OF DRAWINGS

FIG. 1 is a schematic view showing the configuration of a photoelectric converter according to an embodiment of this invention.

FIG. 2 is a schematic view of a plasma apparatus for manufacturing the photoelectric converter shown in FIG. 1.

FIG. 3 is a graph showing the relationship between the normalized transmittance and the plasma treatment temperature.

FIG. 4 is an illustration showing surface SEM images of transparent conductive films in the case of subjecting transparent conductive film substrates to no plasma treatment, hydrogen plasma treatment, and methane plasma treatment.

FIG. 5 is a graph showing the waveforms of Sn3d 5/2 peaks in the case of performing no plasma treatment, methane plasma treatment, and hydrogen plasma treatment at a temperature of 190° C.

FIG. 6 is a graph showing the relationship between the normalized transmittance and the CH₄ gas flow rate ratio during methane plasma treatment.

FIG. 7 is a flowchart showing a method for manufacturing the photoelectric converter shown in FIG. 1.

FIG. 8 is a flowchart showing detailed sub-steps of Step (c) shown in FIG. 7.

FIG. 9 is a flowchart showing detailed sub-steps of Step (d) shown in FIG. 7.

### DESCRIPTION OF EMBODIMENTS

Embodiments of the present invention are described in detail with reference to drawings. In the drawings, the same or equivalent portions are denoted by the same reference numerals and the description thereof is not repeated. In an embodiment in this specification, a semiconductor device fabricated on a transparent conductive substrate is referred to as a photoelectric converter. The reliability and properties of the photoelectric converter have been evaluated, whereby the effect of methane plasma treatment applied to the transparent conductive substrate has been evaluated. Properties of the semiconductor device fabricated on the transparent conductive substrate are known to be significantly affected by the transmittance of a transparent conductive film. Changes in properties of the transparent conductive film by plasma treatment are reflected on properties of the photoelectric converter. Since it is readily appreciated that properties of the interface between a photoelectric conversion layer and the transparent conductive film significantly affect the reliability of the photoelectric converter, a substrate-rinsing effect by methane plasma treatment has been evaluated from two sides: the reliability and properties of the photoelectric converter. As used herein, the semiconductor device is not limited to the photoelectric converter and may be a semiconductor device formed on a transparent conductive substrate.

In this specification, the term “amorphous phase” refers to such a state that silicon (Si) atoms or the like are arranged at random. The term “microcrystalline phase” refers to such a state that grains of Si that have a size of about 10 nm to 100 nm are present in a random network of Si atoms or the like. Furthermore, amorphous silicon is expressed as “a-Si”. This expression means that in fact, hydrogen (H) atoms are contained. Likewise, amorphous silicon carbide (a-SiC), amorphous silicon oxide (a-SiO), amorphous silicon nitride (a-SiN), amorphous silicon germanide (a-SiGe), amorphous germanium (a-Ge), microcrystalline silicon carbide (μc-SiC), microcrystalline silicon oxide (μc-SiO), microcrystalline silicon nitride (μc-SiN), microcrystalline silicon (μc-Si), microcrystalline silicon germanide (μc-SiGe), and microcrystalline germanium (μc-Ge) mean that hydrogen (H) atoms are contained.

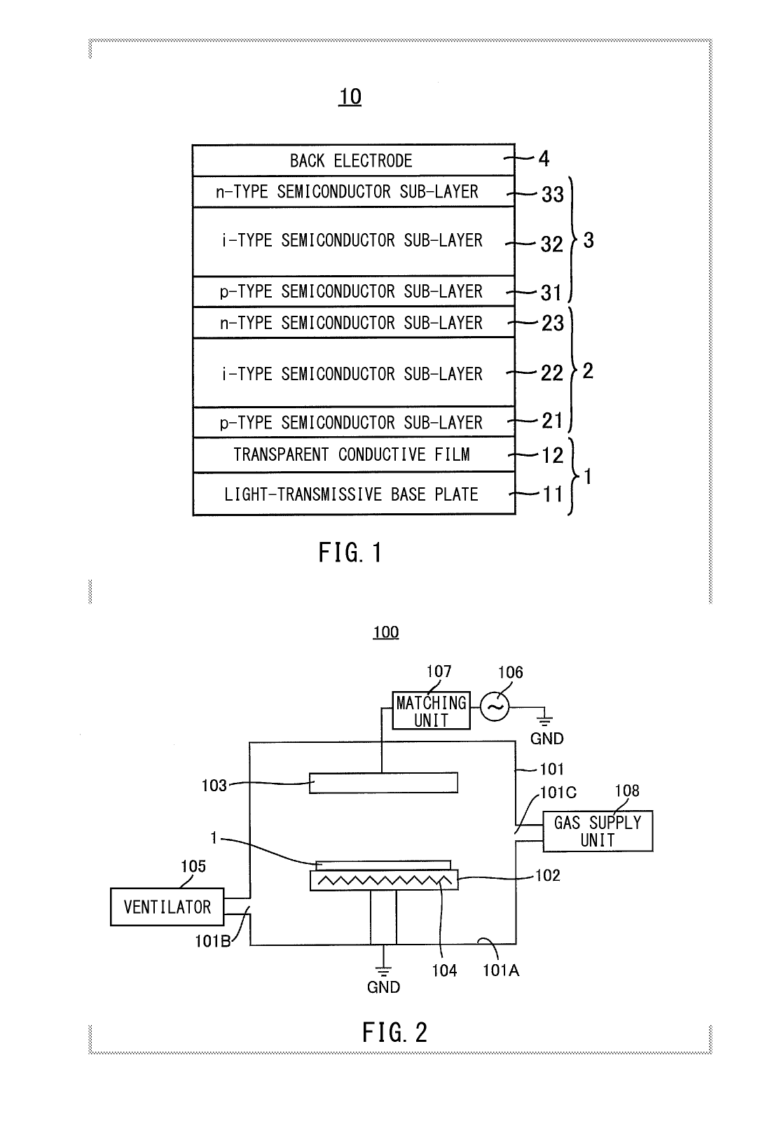

FIG. 1 is a schematic view showing the configuration of a photoelectric converter according to an embodiment of this invention. The photoelectric converter 10 according to this embodiment of this invention may be a multi-junction photoelectric converter including a transparent conductive substrate 1, photoelectric conversion layers 2 and 3 stacked thereon, and a back electrode 4 as shown in FIG. 1 or may be a single-junction photoelectric converter, which is not shown, including a single photoelectric conversion layer.

A material for a photoelectric conversion layer of the photoelectric converter 10 shown in FIG. 1 is not particularly limited and may have photoelectric conversion properties. Among silicon-based semiconductors, for example, Si, SiGe, SiC, or the like is preferably used. As an amorphous pin structure stack body, a p-i-n structure stack body of a hydrogenated amorphous silicon-based semiconductor (a-Si:H) is particularly preferred. As a microcrystalline pin structure stack body, a p-i-n structure stack body of a hydrogenated microcrystalline silicon-based semiconductor (μc-Si:H) is particularly preferred. The photoelectric conversion layer is not limited to a silicon-based semiconductor material and may be composed of a compound semiconductor layer, made of CdTe or CIGS, formed on tin oxide (SnO₂), indium oxide (In₂O₂), or indium tin oxide (ITO) serving as a transparent conductive film.

The photoelectric conversion layer 2 is placed on the transparent conductive substrate 1. The photoelectric conversion layer 3 is placed on the photoelectric conversion layer 2. The back electrode 4 is placed on the photoelectric conversion layer 3.

The transparent conductive substrate 1 includes a light-transmissive base plate 11 and a transparent conductive film 12. The light-transmissive base plate 11 is made of, for example, glass or a transparent resin such as polyimide. The transparent conductive film 12 mainly contains tin oxide (SnO₂), indium tin oxide (ITO), or indium oxide (In₂O₂). The transparent conductive film 12 is placed on the light-transmissive base plate 11.

The photoelectric conversion layer 2 includes a p-type semiconductor sub-layer 21, an i-type semiconductor sub-layer 22, and an n-type semiconductor sub-layer 23. The p-type semiconductor sub-layer 21 is placed in contact with the transparent conductive film 12. The i-type semiconductor sub-layer 22 is placed in contact with the p-type semiconductor sub-layer 21. The n-type semiconductor sub-layer 23 is placed in contact with the i-type semiconductor sub-layer 22.

The p-type semiconductor sub-layer 21 has an amorphous phase and is made of, for example, p-type amorphous silicon carbide (p-type a-SiC). The p-type semiconductor sub-layer 21 preferably has a thickness of 3 nm to 60 nm and more preferably 10 nm to 30 nm.

The i-type semiconductor sub-layer 22 has an amorphous phase and is made of, for example, i-type amorphous silicon (i-type a-Si). The i-type semiconductor sub-layer 22 preferably has a thickness of 100 nm to 500 nm and more preferably 200 nm to 400 nm.

The n-type semiconductor sub-layer 23 has an amorphous phase and is made of, for example, n-type amorphous silicon (n-type a-Si). The n-type semiconductor sub-layer 23 preferably has a thickness of 3 nm to 60 nm and more preferably 10 nm to 30 nm.

The photoelectric conversion layer 3 includes a p-type semiconductor sub-layer 31, an i-type semiconductor sub-layer 32, and an n-type semiconductor sub-layer 33. The p-type semiconductor sub-layer 31 is placed in contact with the n-type semiconductor sub-layer 23 of the photoelectric conversion layer 2. The i-type semiconductor sub-layer 32 is placed in contact with the p-type semiconductor sub-layer 31. The n-type semiconductor sub-layer 33 is placed in contact with the i-type semiconductor sub-layer 32.

The p-type semiconductor sub-layer 31 has a microcrystalline phase and is made of, for example, p-type microcrystalline silicon (p-type μd-Si). The p-type semiconductor sub-layer 31 preferably has a thickness of 3 nm to 60 nm and more preferably 10 nm to 30 nm.

The i-type semiconductor sub-layer 32 has a microcrystalline phase and is made of, for example, i-type microcrystalline silicon (i-type μd-Si). The i-type semiconductor sub-layer 32 preferably has a thickness of 1,000 nm to 5,000 nm and more preferably 2,000 nm to 4,000 nm.

The n-type semiconductor sub-layer 33 has a microcrystalline phase and is made of, for example, n-type microcrystalline silicon (n-type μd-Si). The n-type semiconductor sub-layer 33 preferably has a thickness of 3 nm to 300 nm and more preferably 10 nm to 30 nm.

The back electrode 4 is placed in contact with the n-type semiconductor sub-layer 33 of the photoelectric conversion layer 3 and is made of, for example, zinc oxide (ZnO) or silver (Ag).

FIG. 2 is a schematic view of a plasma apparatus for manufacturing the photoelectric converter 10 shown in FIG. 1. Referring to FIG. 2, the plasma apparatus 100 includes a reaction chamber 101, a support table 102, an electrode 103, a heater 104, a ventilator 105, a high-frequency power supply 106, a matching unit 107, and a gas supply unit 108.

The separation membrane 101 is electrically connected to a ground potential GND. The support table 102 is fixed on the bottom surface 101A of the reaction chamber 101. This electrically connects the support table 102 to the ground potential GND.

The electrode 103 is placed in the reaction chamber 101 so as to be parallel to the support table 102. The heater 104 is placed in the support table 102.

The ventilator 105 is connected to the reaction chamber 101 through a vent 101B. The high-frequency power supply 106 and the matching unit 107 are located between the electrode 103 and the ground potential GND and are connected in series to each other. The gas supply unit 108 connected to the reaction chamber 101 through a gas inlet 101C.

The support table 102 supports the transparent conductive substrate 1. The heater 104 heats the transparent conductive substrate 1 to a desired temperature.

The ventilator 105 includes, for example, a gate valve, a turbo-molecular pump, a mechanical booster pump, and a rotary pump. The gate valve is located closest the reaction chamber 101. The turbo-molecular pump, the mechanical booster pump, and the rotary pump are connected in series to each other such that the turbo-molecular pump is located on the gate valve side and the rotary pump is located most downstream.

The ventilator 105 exhausts gas from the reaction chamber 101 through the vent 101B to evacuate the reaction chamber 101 and sets the pressure in the reaction chamber 101 to a desired pressure with the gate valve.

The high-frequency power supply 106 generates 8-100 MHz high-frequency power and supplies the generated high-frequency power to the matching unit 107.

The matching unit 107 supplies the high-frequency power supplied from the high-frequency power supply 106 to the electrode 103 with a reflected wave suppressed.

The gas supply unit 108 supplies a methane (CH₄) gas, a hydrogen (H_{z}) gas, a silane (SiH₄) gas, a diborane (B₂H₆) gas, and a phosphine (PH₃) gas to the reaction chamber 101 through the gas inlet 101C.

After the transparent conductive substrate 1 is set on the support table 102, the ventilator 105 exhausts gas from the reaction chamber 101 through the vent 101B to evacuate the reaction chamber 101. The heater 104 heats the transparent conductive substrate 1 to a desired temperature.

When the pressure in the reaction chamber 101 reaches an attained pressure (for example, 1×10⁻⁵ Pa or less), the gas supply unit 108 supplies the CH₄ gas and the H₂ gas to the reaction chamber 101. The ventilator 105 sets the pressure in the reaction chamber 101 to a desired pressure with the gate valve.

Then, the high-frequency power supply 106 supplies a desired high-frequency power to the electrode 103 through the matching unit 107. As a result, plasma is generated between the support table 102 and the electrode 103 and therefore the transparent conductive substrate 1 is treated with plasma using the CH₄ gas and the H₂ gas.

On the other hand, when the gas supply unit 108 supplies the SiH₄ gas and the H₂ gas to the reaction chamber 101, i-type a-Si or i-type μc-Si is deposited on the transparent conductive substrate 1. When the gas supply unit 108 supplies the SiH₄ gas, the H₂ gas, and the B₂H₆ gas to the reaction chamber 101, p-type a-Si or p-type μc-Si is deposited on the transparent conductive substrate 1. When the gas supply unit 108 supplies the SiH₄ gas, the H₂ gas, and the PH₃ gas to the reaction chamber 101, n-type a-Si or n-type μc-Si is deposited on the transparent conductive substrate 1.

In this way, the plasma apparatus 100 plasma-treats the transparent conductive substrate 1 and deposits an a-Si film or the like on the transparent conductive substrate 1 by a plasma CVD (chemical vapour deposition) process.

### [Effect of Methane Plasma Treatment]

In order to confirm the effectiveness of treating the transparent conductive film 12 with plasma using the CH₄ gas, the transparent conductive substrate 1 has been treated with plasma using the CH₄ gas and plasma using the H₂ gas.

In this case, conditions for plasma treatment using the CH₄ gas are as follows: the flow rate of the CH₄ gas is 2.25 slm, the flow rate of the H₂ gas is 10 slm, and the gas flow rate ratio (═CH₄/(CH₄+H₂)) of the flow rate of the CH₄ gas and the flow rate of the H₂ gas is 0.18. Furthermore, the high-frequency power is 0.143 W/cm² and the plasma treatment temperature is 130° C. to 220° C.

In this specification, a treatment step expressed as “methane plasma treatment” means a step of performing plasma treatment using the CH₄ gas only or using the CH₄ gas and the H₂ gas.

On the other hand, conditions for plasma treatment using the H₂ gas only are as follows: the flow rate of the H₂ gas is 10 slm, the high-frequency power is 0.143 W/cm², and the plasma treatment temperature is 130° C. to 220° C. Incidentally, the transparent conductive film 12 is made of SnO₂.

SnO₂ is known to be readily reduced by hydrogen radicals and optical properties thereof are significantly varied by plasma treatment.

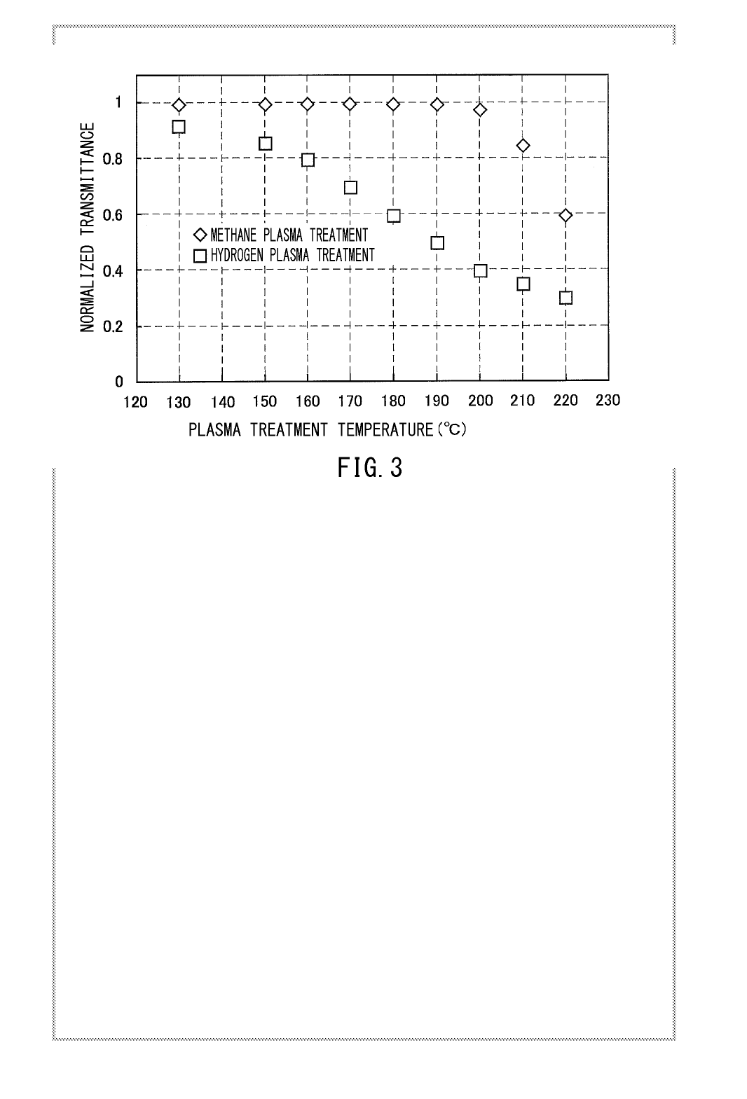

FIG. 3 is a graph showing the relationship between the normalized transmittance and the plasma treatment temperature. Herein, the ordinate represents the normalized transmittance obtained by normalizing the transmittance of plasma-treated SnO₂ at a wavelength of 400 nm with the transmittance of plasma-untreated SnO₂ at a wavelength of 400 nm and the abscissa represents the plasma treatment temperature. Furthermore, rhombic plots show the relationship between the normalized transmittance of SnO₂ subjected to methane plasma treatment and the plasma treatment temperature and square plots show the relationship between the normalized transmittance of SnO₂ subjected to hydrogen plasma treatment and the plasma treatment temperature.

As is clear from FIG. 3, the normalized transmittance of SnO₂ subjected to methane plasma treatment is substantially “1” at a plasma treatment temperature of up to 200° C. and decreases at a plasma treatment temperature of 210° C. or higher.

On the other hand, the normalized transmittance of SnO₂ subjected to hydrogen plasma treatment decreases with an increase in plasma treatment temperature and significantly decreases at a plasma treatment temperature of 170° C. or higher.

As described above, the transmittance of SnO₂ subjected to methane plasma treatment does not decrease at a plasma treatment temperature of up to 200° C.

When the surface of SnO₂ is plasma-treated with a process gas containing a CH₄ gas, Sn atoms in SnO₂ bind to radicals in a vapor phase to vaporize, whereby SnO₂ is etched.

In order to confirm that SnO₂ is etched by methane plasma, an emission spectrum has been analyzed by OES (optical emission spectroscopy) during methane plasma treatment and hydrogen plasma treatment. Emission indicating the presence of Sn in a vapor phase was observed during methane plasma treatment; hence, it was confirmed that a transparent conductive film was etched by methane plasma treatment. Furthermore, from the dependence of the emission spectrum of Sn on the plasma treatment time, it was confirmed that SnO₂ was continuously etched. On the other hand, emission from Sn was not observed during hydrogen plasma treatment; hence, it became apparent that Sn was not vaporized by hydrogen plasma treatment.

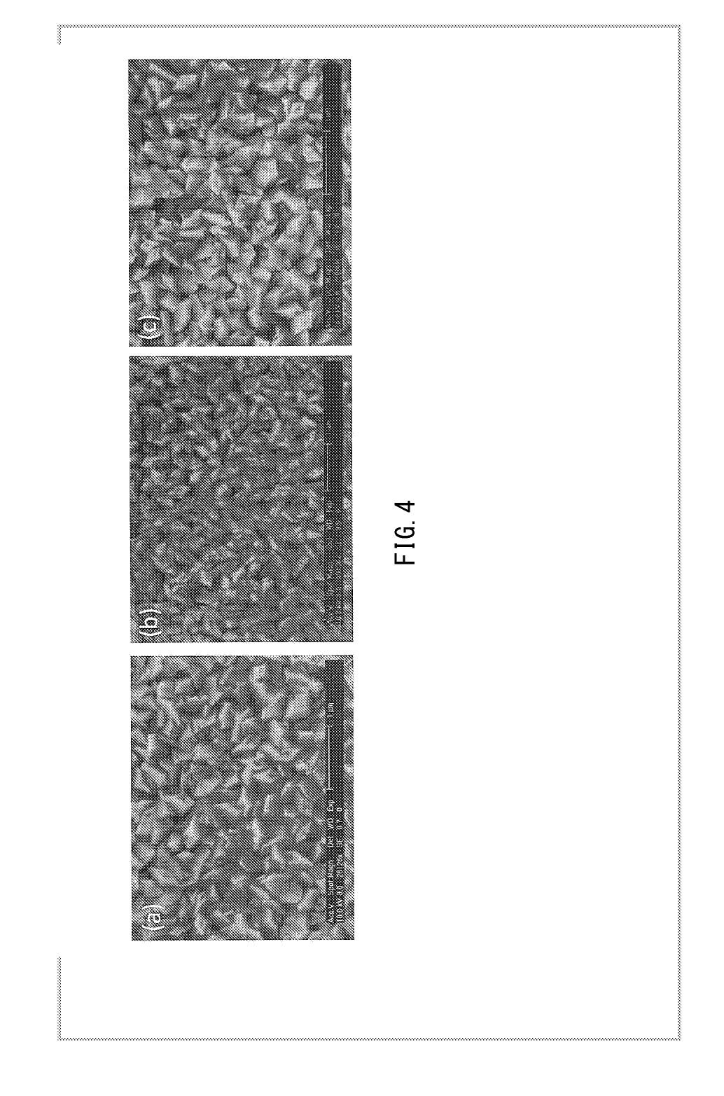

Next, the following images are shown in FIG. 4: surface SEM images in the case of subjecting transparent conductive film substrates to no plasma treatment, hydrogen plasma treatment, and methane plasma for the purpose of confirming the change of surface morphology due to plasma treatment.

The surface SEM images are SEM images in the case of performing no plasma treatment, hydrogen plasma treatment at a plasma treatment temperature of 109° C. under the same conditions as those for plasma treatment performed as shown in FIG. 3, and methane plasma treatment. FIG. 4(a) shows a surface SEM image in the case of performing no plasma treatment. FIG. 4(b) shows a surface SEM image in the case of performing hydrogen plasma treatment. FIG. 4(c) shows a surface SEM image in the case of performing methane plasma treatment.

A surface of the transparent conductive film subjected to hydrogen plasma treatment (FIG. 4(b)) has a larger number of white particles which have a crystal grain size of about 0.250 μm to 0.600 μm and which are on a surface of a SnO₂ crystal as compared to a surface of a crystal subjected to no plasma treatment (FIG. 4(a)). This shows that the surface morphology of the SnO₂ crystal is varied by hydrogen plasma treatment. On the other hand, in the case of performing methane plasma treatment (FIG. 4(c)), such white particles that are observed on a surface of a crystal subjected to hydrogen plasma treatment are not confirmed and substantially the same surface morphology as the surface morphology due to no plasma treatment is maintained.

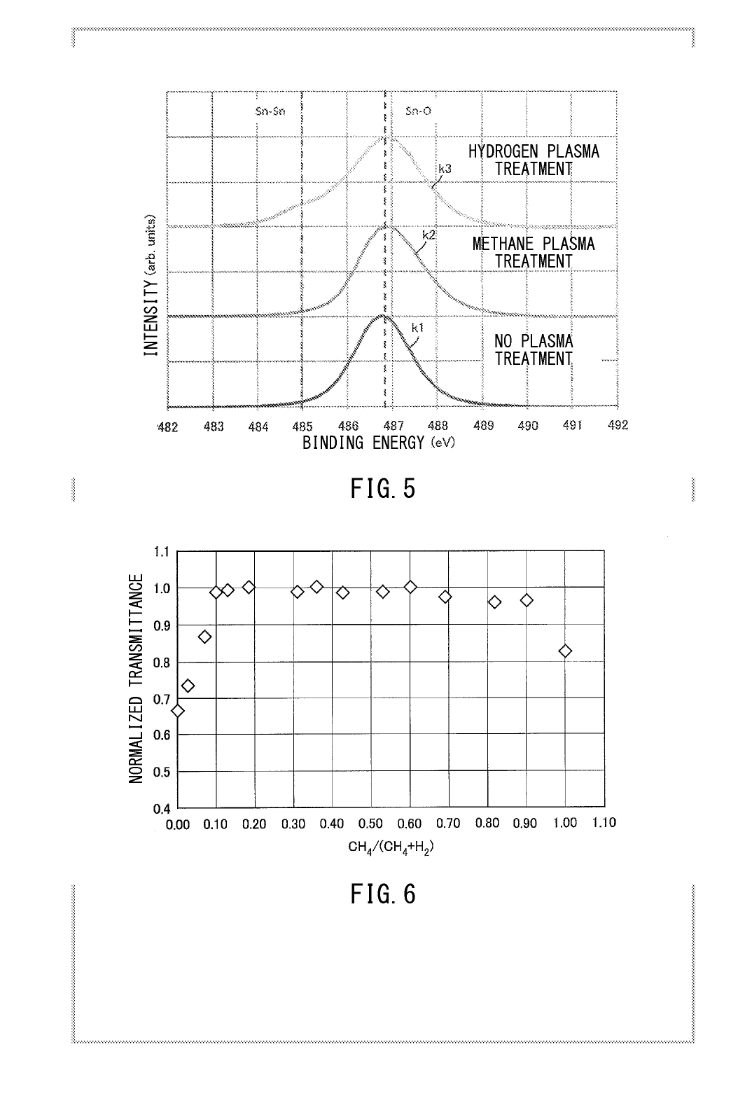

Next, surfaces of SnO₂ crystals subjected to no plasma treatment, hydrogen plasma treatment, and methane plasma treatment as shown in FIG. 4 have been analyzed by X-ray photoelectron spectroscopy (XPS: X-ray photoelectron spectroscopy). Results are shown in FIG. 5.

FIG. 5 is a graph showing the waveforms of Sn3d 5/2 peaks in the case of performing no plasma treatment, methane plasma treatment, and hydrogen plasma treatment at a temperature of 190° C.

In FIG. 5, the ordinate represents the intensity of X-ray photoelectron spectroscopy and the abscissa represents the binding energy. Furthermore, a curve k1, a curve k2, and a curve k3 indicate the waveforms of Sn3d 5/2 peaks in the case of performing no plasma treatment, methane plasma treatment, and hydrogen plasma treatment, respectively. A peak due to a Sn—O bond which is a main component of SnO₂ is observed at 486.7 eV and a peak due to a Sn—Sn bond is observed at 484.9 eV from an XPS spectrum. In a spectrum in the case of performing hydrogen plasma treatment, a Sn—Sn bond peak is increased as compared to no plasma treatment and methane plasma treatment; hence, it has become apparent that the white fine particles observed on the SnO₂ crystal surface in FIG. 4(b) are Sn precipitated by the reduction action of hydrogen plasma.

Next, whether a carbon film is deposited on the surface of SnO₂ by methane plasma treatment has been analyzed by X-ray photoelectron spectroscopy in order to verify the reducibility of a transparent conductive film by methane plasma treatment, the deposition of the carbon film, and the possibility of etching stop due to the deposition of the carbon film on SnO₂. In X-ray photoelectron spectroscopy, the following peaks have been evaluated: peaks relating to carbon, oxygen, and tin in substrates subjected to no surface treatment, methane plasma treatment, and hydrogen plasma treatment. Conditions for methane plasma treatment are as follows: the flow rate of the CH₄ gas is 2.25 slm, the flow rate of the H₂ gas is 10 slm, the gas flow rate ratio (═CH₄/(CH₄+H₂)) of the flow rate of the CH₄ gas and the flow rate of the H₂ gas is 0.18. Furthermore, the high-frequency power is 0.143 W/cm² and the plasma treatment temperature is 190° C. Conditions for plasma treatment using the H₂ gas are as follows: the flow rate of the H₂ gas is 10 slm, the high-frequency power is 0.143 W/cm², and the plasma treatment temperature is 190° C.

A peak relating to carbon on the surface of SnO₂ subjected to methane plasma treatment shows the same spectrum as a peak relating to carbon on the surface of SnO₂ subjected to no plasma treatment and also has shown the same spectrum as a peak relating to carbon on the surface of a substrate which is not SnO₂.

It has become clear that only a peak due to surface contamination is detected because the carbon peak is eliminated by sputtering the surface of SnO₂. It has become clear that any carbon film is not deposited on the surface of SnO₂ because a peak due to a Sn—O bond is observed by surface photoelectron spectroscopy.

Peaks (a C—C bond and a C—H bond), which are not shown, relating to carbon on the surface of SnO₂ subjected to methane plasma treatment have shown the same spectrum as peaks relating to carbon on the surface of SnO₂ subjected to no plasma treatment. Furthermore, in the measurement of surfaces by X-ray photoelectron spectroscopy, only a peak due to a Sn—O bond has been observed except the peaks relating to carbon and any peak due to a Sn—C bond has not been observed; hence, there is a high possibility that carbon chemically bonded to a surface of a substrate is not present and an attached or adsorbed organic component has been merely detected. Thus, it is conceivable that any carbon film is not deposited as a result of performing methane plasma treatment.

FIG. 5 is further considered in detail. Regarding the Sn3d 5/2 peaks, the peak due to the Sn—O bond, which is a main component of SnO₂, has been observed at 486.7 eV and the peak due to the Sn—Sn bond, which has been precipitated by reduction, has been observed at 484.9 eV as described above. The reduction ratio can be determined from the ratio of the two peaks.

In the case of performing hydrogen plasma treatment, the increase of the peak due to the Sn—Sn bond has been observed as described above (refer to the curve k3). Thus, it is conceivable that SnO₂ is reduced by performing hydrogen plasma treatment, Sn is thereby precipitated as shown in FIG. 4(b), and the precipitation of Sn by hydrogen plasma treatment is the reason why the reduction of transmittance during hydrogen plasma treatment is large as shown in FIG. 3.

On the other hand, in the case of performing methane plasma treatment and in the case of performing no plasma treatment, any peak due to a Sn—Sn bond has not been observed but only the peak due to the Sn—Sn bond has been observed (refer to the curves k1 and k2). Thus, it is clear that SnO₂ is not reduced or no Sn deposits remain on the surface in the case of performing methane plasma treatment. This agrees with the fact that the transmittance is not reduced by methane plasma treatment as shown in FIG. 3.

As a conclusion of the above, FIG. 3 is summarized as follows: in hydrogen plasma treatment, the precipitation of Sn on a surface of a substrate by the reduction of SnO₂ is a cause of low transmittance; however, in methane plasma treatment, SnO₂ is not reduced and the fact that no Sn deposits remain on a surface is the reason why the transmittance is not reduced at a treatment temperature of 200° C. or lower.

Next, the influence of the H₂ gas during methane plasma treatment is considered.

In the above conditions for methane plasma treatment, the gas flow rate ratio (═CH₄/(CH₄+H₂)) of the flow rate of the CH₄ gas and the flow rate of the H₂ gas is 0.18. Even though the proportion of the H₂ gas is high in the gas flow rate ratio of the CH₄ gas and the H₂ gas as described above, the reduction in transmittance of SnO₂ due to reduction by hydrogen radicals is not observed. Any peak due to a Sn—Sn bond has not been observed by X-ray photoelectron spectroscopy. In order to investigate a cause thereof, the amount of hydrogen radicals during hydrogen plasma treatment using hydrogen only was compared to the amount of hydrogen radicals during methane plasma treatment from an OES spectrum. As a result, it has become clear that the amount of hydrogen radicals during plasma treatment using a mixture of hydrogen and methane is reduced to about one-fourth of the amount of hydrogen radicals during hydrogen plasma treatment (not shown).

That is, the production of hydrogen radicals is suppressed by mixing methane and therefore the reduction of SnO₂ by hydrogen radicals is suppressed. It has become apparent that this is the reason why the reduction of transmittance is suppressed. Furthermore, it has been confirmed that the deposition of any carbon film is not observed under methane plasma treatment conditions in which the CH₄ gas flow rate ratio is low as described above.

The relationship between the CH₄ gas flow rate ratio (═CH₄/(CH₄+H₂)) and the normalized transmittance in the case of performing methane plasma treatment by varying the CH₄ gas flow rate ratio is shown in FIG. 6. Herein, the normalized transmittance refers to one obtained by normalizing the transmittance of a transparent conductive film subjected to methane plasma treatment or hydrogen plasma treatment at a wavelength of 400 nm with the transmittance of the transparent conductive film subjected to no plasma treatment at a wavelength of 400 nm.

It is conceivable that when the CH₄ gas flow rate ratio is within the range CH₄/(CH₄+H₂)<0.1, the effect of suppressing hydrogen radicals by methane is not sufficient and therefore the reduction of transmittance is caused by the absorption of Sn precipitated by the reduction of SnO₂. Within the range CH₄/(CH₄+H₂)≧0.1, the significant reduction of transmittance is not observed. Therefore, it is conceivable that the effect of suppressing hydrogen radicals is sufficiently obtained.

Next, an influence in the case where the flow rate ratio of the CH₄ gas is large in methane plasma treatment is considered. Under methane plasma treatment conditions in which the flow rate ratio of the CH₄ gas is large, it cannot be denied that carbon films are deposited on the surface of SnO₂ at once. In the case where the carbon films function as protective films against hydrogen plasma treatment, it is predicted that the reduction of SnO₂ is stopped and therefore the reduction in transmittance of SnO₂ is suppressed, which is not contradictory to results of FIG. 6. However, there is a concern that the formation of a carbon film between a transparent conductive film and a photoelectric conversion layer has an adverse influence on the photoelectric conversion efficiency of itself.

Regarding the deposition of a carbon film on a transparent conductive film, it has been reported that the photoelectric conversion efficiency is increased in such a manner that a carbon film is deposited on a transparent conductive film made of zinc oxide (Patent Literatures 3, 4, and 5). However, a similar effect has not been confirmed on SnO₂.

Therefore, in order to evaluate the influence of the deposition of a carbon film produced by methane plasma, Sn intentionally precipitated by hydrogen plasma treatment in advance has been subjected to methane plasma treatment with the flow rate ratio of a CH₄ gas varied and the surface thereof has been observed by SEM after plasma treatment. In the case of methane plasma conditions in which the etching of precipitated Sn is dominant, Sn is removed and a smooth SnO₂ surface is expected to appear. However, in the case of methane plasma conditions in which the deposition of the carbon film is dominant, the carbon film serves as a protective film against etching and therefore the reduction in number of particles of precipitated Sn is stopped; hence, a surface with fine irregularities due to the Sn particles is supposed to appear.

As a result of the above evaluation, in the case of methane plasma conditions in which the flow rate ratio of the CH₄ gas is greater than 0.7, it has been confirmed by surface SEM observation that the number of particles of Sn is reduced immediately after the start of methane plasma treatment; the reduction in number of the particles is, however, gradually stopped; and Sn remains on a surface. In particular, when the flow rate ratio of the CH₄ gas is 0.8, 0.9, and 1.0, the deposition of Sn on a surface of a substrate has been confirmed.

This is probably because the etching of precipitated Sn is stopped by the deposition of the carbon film; hence, if the time of methane plasma treatment is prolonged, precipitated Sn cannot be completely removed. Since precipitated Sn remains, the transmittance has exhibited a lower value as compared to a value obtained in the case where the flow rate ratio of the CH₄ gas is 0.1 to 0.7. From the above, it has become apparent that in the case of performing methane plasma treatment under conditions in which the flow rate ratio of the CH₄ gas is greater than 0.7, the deposition of the carbon film is dominant. On the other hand, in the case of performing methane plasma treatment in a region of CH₄/(CH₄+H₂) 0.7, it has been confirmed that precipitated Sn is completely removed by methane plasma treatment, a smooth surface morphology is exhibited, and the transmittance is substantially equal to no plasma treatment.

From the above, it has been found that there is a region in which SnO₂ can be more efficiently etched without reducing the transmittance of SnO₂ within a range where the reduction rate by hydrogen is substantially equal to the etching rate by CH₄ radicals on the basis of a temperature region in which the reduction action of hydrogen is low, the effect of etching Sn by CH₄ radicals, and the effect of suppressing the production of hydrogen radicals by the introduction of the CH₄ gas. In the range where the reduction and etching rates are substantially equal to each other, the precipitation of Sn on a surface of the transparent conductive film (FIG. 4(c)) is not observed or the transmittance is not reduced. This shows that the reduction and etching rates are substantially equal to each other. From these results, it has been confirmed that a surface of a transparent conductive film can be etched by methane plasma treatment without varying the surface morphology with the transmittance maintained.

Thus, it has become clear that the reduction and etching rates are substantially equal to each other with no carbon film deposited when the gas flow rate ratio (═CH₄/(CH₄+H₂)) is within the range 0.1 (CH₄/(CH₄+H₂))≦0.7, it is effective to subjecting the transparent conductive film 12 to methane plasma treatment at a plasma treatment temperature (=the temperature of the transparent conductive substrate 1) of 200° C. or lower, and a contaminated surface layer contaminated with pollutants can be readily removed by methane plasma treatment under the above conditions without reducing transmittance properties of the transparent conductive film and without depositing any carbon film.

### [Preparation of Photoelectric Converter]

Photoelectric conversion properties and reliability due to methane plasma treatment have been evaluated by applying a technique for cleaning a surface of a transparent conductive film by methane plasma treatment to the preparation of a photoelectric converter. In an example, a photoelectric converter having an integrated structure was manufactured by a method below. In this embodiment, a transparent conductive substrate with a size of 1,000 mm×1,400 mm was prepared. The substrate had a transparent conductive film, made of SnO₂, formed on a surface therefore. In usual, transparent conductive substrates are brought into a factory manufacturing photoelectric converters from glass makers in such a state that the transparent conductive substrates are stacked. Slip sheets are placed between the substrates and transparent conductive films such that the substrates and the transparent conductive films are prevented from being damaged. The transparent conductive substrates brought into the factory are in an unrinsed state.

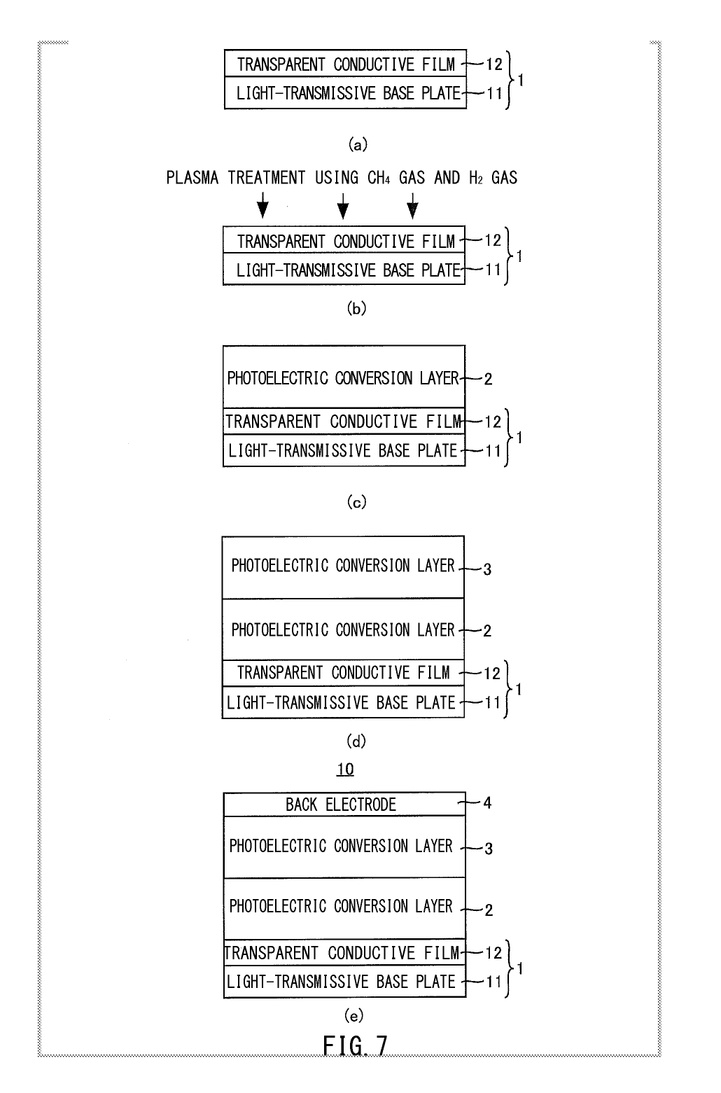

FIG. 7 is a flowchart showing a method for manufacturing the photoelectric converter 10 shown in FIG. 1. In this embodiment, a tandem photoelectric converter was prepared by depositing two photoelectric conversion layers having a pin structure consisting of a p-layer, i-layer, and n-layer arranged on the substrate side in that order. Herein, a photoelectric conversion layer, located on the light incident side, having the pin structure is defined as a top layer and a photoelectric conversion layer, located on the back electrode 4 side, having the pin structure is defined as a bottom layer.

As soon as the manufacture of the photoelectric converter 10 is started, the transparent conductive substrate 1 passes through an atmosphere with cleanliness lower than ISO 14644-1 Class 4 without being rinsed. After first isolation grooves are formed at predetermined intervals by a laser scribing process, the transparent conductive substrate 1 is brought into the reaction chamber 101 of the plasma apparatus 100 and is then set on the support table 102 (refer to Step (a) shown in FIG. 7). The term “substrate rinsing” as used herein refers to a step of removing impurities on a surface of a transparent conductive film by, for example, pure water rinsing using pure water, chemical rinsing, ultrasonic rinsing, and the like to clean the surface of the transparent conductive film and drying the transparent conductive film.

After Step (a), the transparent conductive film 12 of the transparent conductive substrate 1 is treated with methane plasma (refer to Step (b) shown in FIG. 7).

Since radicals containing Sn etched by CH₄ may possibly remain in the reaction chamber after methane plasma treatment, the evacuation time needs to be sufficiently long. The adequate evacuation time is about 60 seconds to 600 seconds. In Example 2 below, evacuation was performed for 300 seconds. A replacement evacuation step may be performed instead of a simple evacuation step. The replacement evacuation step is a step in which after a substitution gas is introduced into a reaction chamber, the reaction chamber is evacuated. Inert gases such as a nitrogen gas, an argon gas, and a helium gas can be used as the substitution gas. A gas species used in the next step is preferably used because there is no influence of containing impurities due to the remaining of the substitution gas. In particular, in the case of forming a photoelectric conversion layer in the same reaction chamber immediately after methane plasma treatment, the above residue may possibly be incorporated into the photoelectric conversion layer to cause reductions in properties and therefore the replacement evacuation step is preferably performed. Therefore, in Example 1 below, a replacement evacuation step below was added after methane plasma treatment. The replacement evacuation step in Example 1 is a step in which a hydrogen gas is introduced into a reaction chamber, the introduction of the hydrogen gas is stopped when the pressure in the reaction chamber reaches a preset pressure or more, followed by exhausting the substitution gas (=the hydrogen gas). This replacement evacuation step is repeated three times between methane plasma treatment and the formation of a photoelectric conversion layer.

The photoelectric conversion layers 2 and 3, which has the pin structure, are sequentially deposited on the transparent conductive film 12 of the transparent conductive substrate 1 by a plasma CVD process (refer to Steps (c) and (d) shown in FIG. 7). Thereafter, a sample is taken out of the plasma apparatus 100. Second isolation grooves were formed in silicon semiconductor layers (the photoelectric conversion layers 2 and 3) at predetermined intervals by the laser scribing process. This allows the second isolation grooves to serve as contact lines for electrically connecting the neighboring silicon semiconductor layers in series to each other.

After the second isolation grooves are formed, the back electrode 4 is formed on the photoelectric conversion layer 3 by a vapor deposition process, a sputtering process, a printing process, and the like so as to cover the silicon semiconductor layers. Third isolation grooves are formed at predetermined intervals by the laser scribing process so as to communicate with the silicon semiconductor layers (the photoelectric conversion layers 2 and 3) and the back electrode 4. This formed a string in which the photoelectric conversion layers 2 and 3 separated by the pitch of the third isolation grooves were connected in series to each other. Thereafter, in an edge portion of the substrate, the transparent conductive film 12, the silicon semiconductor layers (the photoelectric conversion layers 2 and 3), and the back electrode 4 were removed by the laser scribing process, a sandblasting process, and the like. This completes the photoelectric converter 10 (refer to Step (e) shown in FIG. 7). A trimming region is formed by removing the edge portion of the substrate, whereby the insulating performance (dielectric strength) of the photoelectric converter was capable of being enhanced.

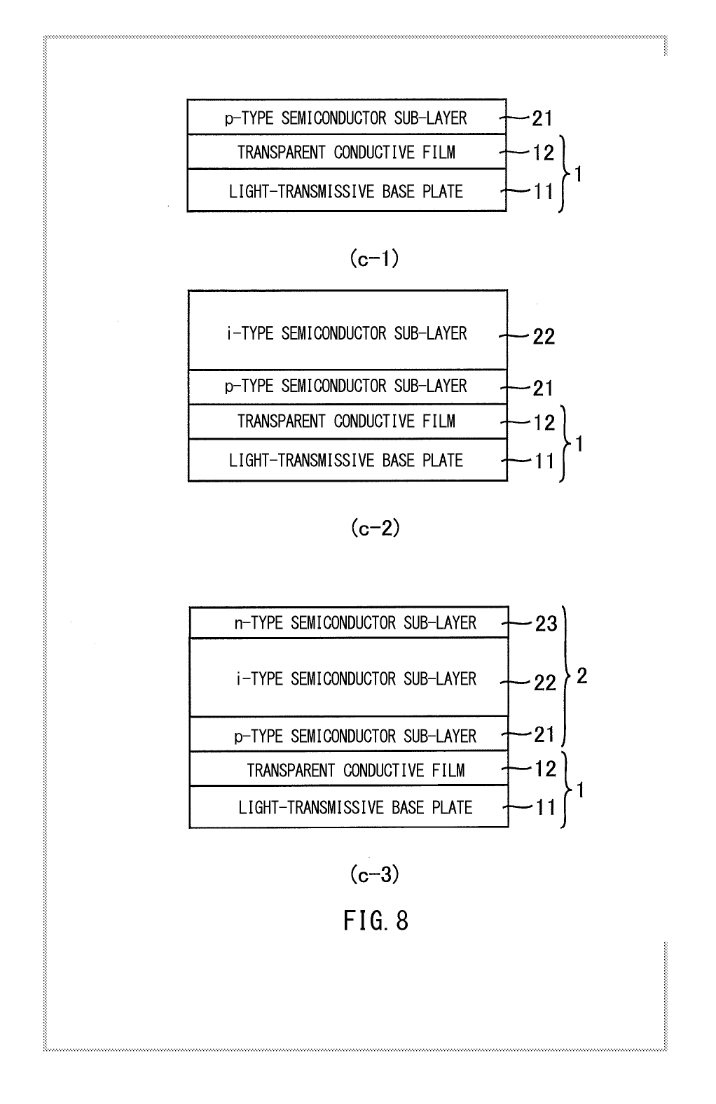

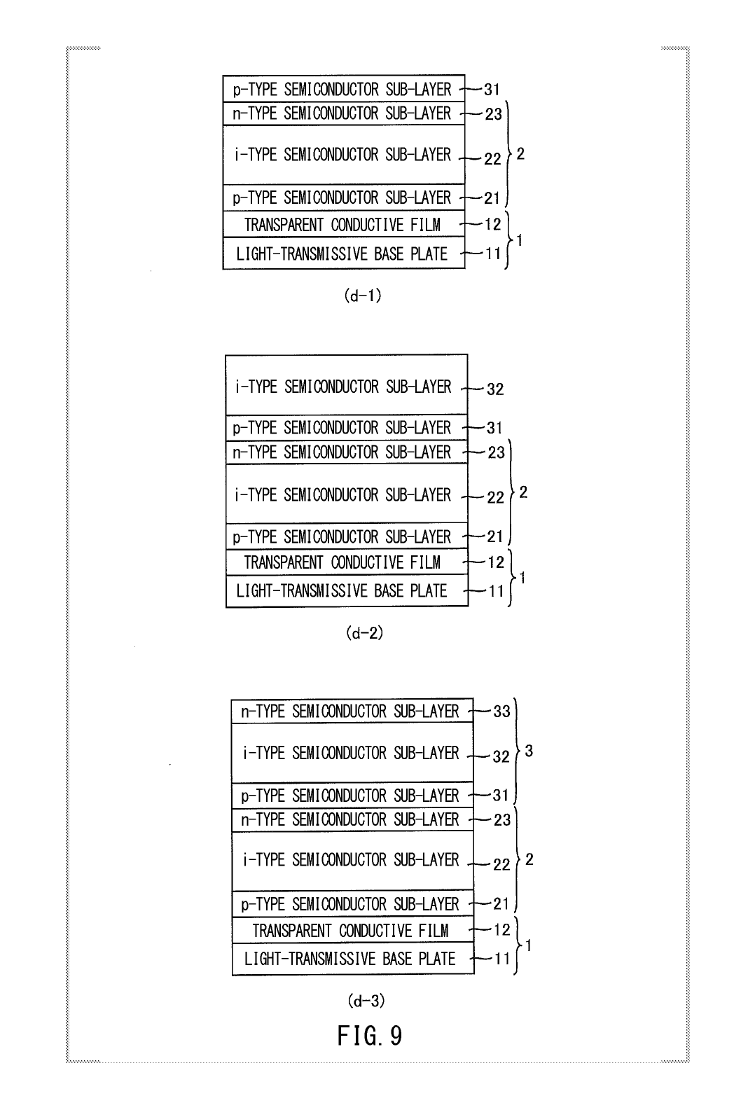

FIG. 8 is a flowchart showing detailed sub-steps of Step (c) shown in FIG. 7. FIG. 9 is a flowchart showing detailed sub-steps of Step (d) shown in FIG. 7.

As shown in FIG. 8, after Step (b) shown in FIG. 7, the p-type semiconductor sub-layer 21, the i-type semiconductor sub-layer 22, and the n-type semiconductor sub-layer 23 are deposited on the transparent conductive film 12 in that order (refer to Sub-steps (c-1) to (c-3) shown in FIG. 8). This forms the photoelectric conversion layer 2, which has the pin structure, on the transparent conductive film 12.

As shown in FIG. 9, after Step (c) shown in FIG. 7, the p-type semiconductor sub-layer 31, the i-type semiconductor sub-layer 32, and the n-type semiconductor sub-layer 33 are deposited on the photoelectric conversion layer 2 in that order (refer to Sub-steps (d-1) to (d-3) shown in FIG. 9). This forms the photoelectric conversion layer 3, which has the pin structure, on the photoelectric conversion layer 2.

As described above, Steps (c) and (d) shown in FIG. 7 are continuously performed in the reaction chamber 101 and therefore the p-type semiconductor sub-layer 21, the i-type semiconductor sub-layer 22, the n-type semiconductor sub-layer 23, the p-type semiconductor sub-layer 31, the i-type semiconductor sub-layer 32, and the n-type semiconductor sub-layer 33, which form the photoelectric conversion layer 2 or 3, are continuously deposited on the transparent conductive film 12 by switching material gases using a plasma CVD. As a result, the contamination of interfaces between the semiconductor sub-layers with impurities such as oxygen is suppressed and therefore the photoelectric conversion layers 2 and 3 can be prepared so as to have excellent interface properties.

Incidentally, in FIGS. 7 to 9, the first isolation grooves, the second isolation grooves, and the third isolation grooves are omitted.

### Example 1

A photoelectric converter was prepared in accordance with Steps (a) to (e) (including Sub-steps (c-1) to (c-3) shown in FIG. 8 and Sub-steps (d-1) to (d-3) shown in FIG. 9) shown in FIG. 7. Thereafter, resin sealing, a back protective sheet, or a back glass substrate was covered using a vacuum laminator and a terminal box with terminals for extracting power to outside was attached, whereby a solar cell module A was prepared. In this case, conditions for methane plasma treatment in Step (b) shown in FIG. 7 are as follows: the flow rate of an H₂ gas is 10 slm, the flow rate of a CH₄ gas is 2.25 slm, the high-frequency power is 0.143 W/cm², and the plasma treatment temperature is 190° C. A transparent conductive film 12 is made of SnO₄.

### Example 2

A solar cell module B was prepared in substantially the same manner as that described in Example 1 except that no replacement evacuation step was present between Steps (b) and (c) of Steps (a) to (e) (including Sub-steps (c-1) to (c-3) shown in FIG. 8 and Sub-steps (d-1) to (d-3) shown in FIG. 9) shown in FIG. 7 and the time of evacuation performed after methane plasma treatment was changed to 60 seconds to 300 seconds.

### Comparative Example 1

A solar cell module C was prepared in substantially the same manner as that described in Example 1 except that a transparent conductive film 12 of a transparent conductive substrate 1 was subjected to hydrogen plasma treatment instead of Steps (a) to (e) (including Sub-steps (c-1) to (c-3) shown in FIG. 8 and Sub-steps (d-1) to (d-3) shown in FIG. 9) shown in FIG. 7. In this case, conditions for hydrogen plasma treatment are as follows: the flow rate of an H₂ gas is 10 slm, the high-frequency power is 0.143 W/cm², and the plasma treatment temperature is 190° C.

### Comparative Example 2

A photoelectric converter was prepared in accordance with Steps (a) to (e) (including Sub-steps (c-1) to (c-3) shown in FIG. 8 and Sub-steps (d-1) to (d-3) shown in FIG. 9) shown in FIG. 7. Thereafter, resin sealing, a back protective sheet, or a back glass substrate was covered using a vacuum laminator and a terminal box with terminals for extracting power to outside was attached, whereby a solar cell module D was prepared. In this case, conditions for methane plasma treatment in Step (b) shown in FIG. 7 are as follows: the flow rate of an H₂ gas is 0.1 slm, the flow rate of a CH₄ gas is 2.25 slm, the high-frequency power is 0.143 W/cm², and the plasma treatment temperature is 190° C. A transparent conductive film 12 is made of SnO₂. Under the conditions for methane plasma treatment, a carbon film is formed on a transparent conductive film subjected to plasma treatment.

### Reference Example

A solar cell module E was prepared in substantially the same manner as that described in Example 1 except that Steps (a) to (e) (including Sub-steps (c-1) to (c-3) shown in FIG. 8 and Sub-steps (d-1) to (d-3) shown in FIG. 9) shown in FIG. 7 were not performed.

A photoelectric conversion layer 2 included a p-type semiconductor sub-layer 21, i-type semiconductor sub-layer 22, n-type semiconductor sub-layer 23, which had a structure below and which were formed in the same reaction chamber 101 as that used in a plasma treatment step in Example 1, Example 2, Comparative Example 1, Comparative Example 2, and Reference Example.

The p-type semiconductor sub-layer 21 was made of an amorphous silicon carbide layer and was formed using an H₂ gas, an SiH₄ gas, a B₂H₆ gas, and a CH₄ gas. The p-type semiconductor sub-layer 21 has a thickness of 5 nm to 20 nm.

The i-type semiconductor sub-layer 22 was made of an amorphous silicon layer and was formed using the H₂ gas and the SiH₄ gas. The i-type semiconductor sub-layer 22 has a thickness of 220 nm to 320 nm.

The n-type semiconductor sub-layer 23 was made of an amorphous silicon layer and a microcrystalline silicon layer and was formed using the H₂ gas, the SiH₄ gas, and a PH₃ gas. The n-type semiconductor sub-layer 23 has a thickness of 5 nm to 30 nm.

Conditions, other than the above conditions, for forming the p-type semiconductor sub-layer 21, the i-type semiconductor sub-layer 22, and the n-type semiconductor sub-layer 23 were as follows: the deposition pressure was 600 Pa to 1,000 Pa and the deposition temperature was 170° C. to 200° C. The power applied to electrodes for generating plasma was an 11 MHz high-frequency wave pulsed to a periodicity of 400 MHz and the input power was 50 mW/cm² to 180 mW/cm².

A photoelectric conversion layer 3 included a p-type semiconductor sub-layer 31, i-type semiconductor sub-layer 32, n-type semiconductor sub-layer 33, which had a structure below and which were formed in the same reaction chamber 101 as that used in the plasma treatment step in Example 1, Comparative Example 1, Comparative Example 2, and Reference Example.

The p-type semiconductor sub-layer 31 was made of a microcrystalline silicon layer and was formed using the H₂ gas, the SiH₄ gas, the B₂H₆ gas, the CH₄ gas, and an N₂ gas. The p-type semiconductor sub-layer 31 has a thickness of 5 nm to 30 nm.

The i-type semiconductor sub-layer 32 was made of a microcrystalline silicon layer and was formed using the H₂ gas and the SiH₄ gas. The i-type semiconductor sub-layer 32 has a thickness of 1,200 nm to 2,000 nm.

The n-type semiconductor sub-layer 33 was made of an amorphous silicon layer and was formed using the H₂ gas, the SiH₄ gas, and the PH₃ gas. The n-type semiconductor sub-layer 33 has a thickness of 60 nm to 80 nm.

Conditions, other than the above conditions, for forming the p-type semiconductor sub-layer 31, the i-type semiconductor sub-layer 32, and the n-type semiconductor sub-layer 33 were as follows: the deposition pressure was 400 Pa to 1,600 Pa and the deposition temperature was 140° C. to 170° C. The power applied to electrodes for generating plasma was an 11 MHz high-frequency wave and the input power was 90 mW/cm² to 350 mW/cm².

Incidentally, the top layer (photoelectric conversion layer 2) and the bottom layer (photoelectric conversion layer 3) may be formed in different reaction chambers and are preferably formed in the same reaction chamber from the viewpoint of production efficiency.

After the bottom layer was formed, a sample was taken out of the plasma apparatus 100 and second isolation grooves were formed in silicon semiconductor layers (the photoelectric conversion layers 2 and 3) at predetermined intervals by a laser scribing process.

After the second isolation grooves were formed, a back electrode 4 made of ZnO and Ag was formed on the photoelectric conversion layer 3 by a vapor deposition process, a sputtering process, a printing process, and the like so as to cover the silicon semiconductor layers. Third isolation grooves were formed at predetermined intervals by the laser scribing process so as to communicate with the silicon semiconductor layers (the photoelectric conversion layers 2 and 3) and the back electrode 4. Thereafter, in an edge portion (within the range of 10 mm to 20 mm from the outer edge of a substrate) of a substrate, a transparent conductive film 12, the silicon semiconductor layers (the photoelectric conversion layers 2 and 3), and the back electrode 4 were removed by the laser scribing process, a sandblasting process, and the like.

After a tandem photoelectric converter including the two photoelectric conversion layers 2 and 3, which were placed on the transparent conductive film 12 and which had a pin structure, was prepared, an integrated structure was prepared by the laser scribing process. The substrate having the transparent conductive film had a size of 1,000 mm×1,400 mm and the size of a trimming region of the edge portion of the substrate was 12 mm from the outer edge of the substrate.

After the trimming region was formed, resin sealing, a back protective sheet, or a back glass substrate was covered using a vacuum laminator and a terminal box with terminals for extracting power to outside was attached, whereby the solar cell module A, B, C, D, or E was prepared.

The following properties are shown in Table 1: properties of the solar cell module A, which was subjected to methane plasma treatment (Example 1); properties of the solar cell module B, which was subjected to methane plasma treatment (Example 2); properties of the solar cell module C, which was subjected to hydrogen plasma treatment (Comparative Example 1); properties of the solar cell module D, which was subjected to methane plasma treatment under conditions for forming a carbon film (Comparative Example 2); and properties of the solar cell module D, which was subjected to no substrate surface treatment (Reference Example).

TABLE 1

| | Pmax | Isc | Voc | FF | Rs |
|---|---|---|---|---|---|
| Solar cell module E (no substrate | 1.00 | 1.00 | 1.00 | 1.00 | 1.00 |
| surface treatment | | | | | |
| (Reference Example)) | | | | | |
| Solar cell module C (hydrogen | 0.70 | 0.71 | 0.95 | 1.03 | 1.14 |
| plasma treatment | | | | | |
| (Comparative Example 1)) | | | | | |
| Solar cell module D (CH₄ plasma | 0.25 | 0.68 | 1.03 | 0.35 | 15.25 |
| treatment (Comparative Example 2)) | | | | | |
| Solar cell module A (CH₄ plasma | 1.02 | 1.00 | 1.01 | 1.01 | 0.93 |
| treatment (Example 1) | | | | | |
| Solar cell module B (CH₄ plasma | 1.01 | 1.00 | 1.01 | 1.00 | 0.95 |
| treatment (Example 2)) | | | | | |

Incidentally, Table 1 shows properties normalized on the basis of the properties of the solar cell module E, which was not subjected to substrate surface treatment (Reference Example).

For the properties of the solar cell module C, which includes the transparent conductive substrate 1 treated with hydrogen plasma, the short-circuit current Isc is significantly reduced as compared to the case of no substrate surface treatment and therefore Pmax is significantly reduced. The significant reduction of the short-circuit current Isc is probably due to the reduction in transmittance due to the reduction of SnO₂ by hydrogen.

On the other hand, the short-circuit current of the solar cell module A, which was subjected to methane plasma treatment under methane plasma conditions in Example 1, is not reduced, which shows that the reduction of SnO₂ by hydrogen has not occurred. Furthermore, the solar cell module A, which was subjected to methane plasma treatment, has a reduced series resistance Rs and an increased fill factor FF and therefore has enhanced properties as compared to the solar cell module E, which was subjected to no substrate surface treatment. The series resistance Rs was reduced probably because the interface between the photoelectric conversion layer 2 and a clean surface formed by methane plasma treatment was improved.

For the properties of the solar cell module B, which was prepared under the same conditions as those described in Example 1 except that no replacement evacuation step was performed and the time of evacuation performed after methane plasma treatment was changed to 60 seconds to 300 seconds, the power (Pmax) is increased as compared to the solar cell module E, which was subjected to no substrate surface treatment; however, Pmax is reduced as compared to the solar cell module A, which was subjected to the replacement evacuation step, because the fill factor FF is reduced. Thus, it can be said that the contamination of the photoelectric conversion layers with impurities can be suppressed by the effect of reducing residue in the replacement evacuation step and, as a result, the power (Pmax) can be increased.

Furthermore, the influence of forming a carbon film on a transparent conductive film on a photoelectric converter was evaluated. For the properties of the solar cell module D, which was prepared by forming the photoelectric conversion layer on the transparent conductive film subjected to methane plasma treatment under methane plasma conditions in Comparative Example 2, the significant increase in series resistance Rs was observed and therefore the significant reduction in fill factor FF and Pmax was observed. This is probably because a carbon film is formed between the transparent conductive film and the photoelectric conversion layer to prevent the photocurrent generated in the photoelectric conversion layer from flowing into the transparent conductive film and the photoelectric conversion layer is peeled from the transparent conductive film. Thus, it can be said that the formation of the carbon film is an effect undesirable for photoelectric converters.

Patent Literature 2 reports that subjecting a transparent conductive film made of SnO₂ to hydrogen plasma treatment reduces the contact resistance between the transparent conductive film and a photoelectric conversion layer made of amorphous silicon.

However, hydrogen plasma treatment causes the reduction of SnO₂ and the reduction in current of a photoelectric converter due to the reduction in transmittance of a transparent conductive film and therefore reduces properties of the photoelectric converter as described above. Furthermore, the reducing action of hydrogen radicals is likely to be affected by the variation in plasma treatment temperature as shown in FIG. 3 and is a factor causing variations in properties of the photoelectric converter.

On the other hand, as is clear from results of transmittance shown in FIG. 3, methane plasma treatment has a wide process margin with respect to the variation in plasma treatment temperature and is a substrate surface-cleaning technique that can be stably performed with respect to the change of process conditions due to the change in temperature of a substrate.

Performing methane plasma treatment does not cause pollution in the plasma apparatus 100 and enables surfaces of a transparent conductive substrate 1 to be cleaned in the same reaction chamber as a reaction chamber for forming photoelectric conversion layers 2 and 3 in a short time to enhance properties of a photoelectric converter.

Methane plasma treatment has the effect of improving process yield. In order to prepare the above photoelectric converter with the integrated structure, the first isolation grooves are formed in the transparent conductive film 12 by the laser scribing process, whereby the transparent conductive film 12 is isolated in the form of a strip. However, when laser scribing is faulty due to any cause, the insulation resistance of neighboring strip-shaped transparent conductive films is insufficient; hence, photoelectric converters prepared thereon may possibly have reduced properties. However, faulty portions due to laser scribing can be removed by performing methane plasma treatment and therefore the insulation resistance of neighboring strip-shaped transparent conductive films is improved to 0.5 MΩ or more, which is a range not causing the reduction of properties of photoelectric converters. As a result, the reduction in power of a photoelectric converter due to the fault of a laser scribing step can be suppressed, thereby increasing manufacturing yield.

In the case of bringing transparent conductive substrates into a manufacturing step in such a state that slip sheets are placed between the stacked substrates, surfaces of transparent conductive films are contaminated with impurities such as organic substances resulting from the slip sheets and the following problem is supposed: a problem that the adhesion of a photoelectric conversion layer formed on each contaminated transparent conductive film is reduced and therefore the reliability of a photoelectric converter is reduced or a similar problem. The slip sheets themselves have been improved such that even if the slip sheets adhere to the surface of glass, organic components are readily removed by water rinsing; however, a rinsing step needs to be included (Patent Literature 6). Impurities, such as organic substances, adhering to a surface of a film can be removed to a certain extent by performing a rinsing step using pure water. As photoelectric converters are upsized, transparent conductive substrates necessary for photoelectric conversion layers are upsized. In a manufacturing line including a rinsing step, the upsizing of a rinsing/drying system in association with upsizing and the increase of manufacturing costs and takt time cannot be avoided. Furthermore, in a manufacturing line having low-level cleanliness specified in ISO 14644-1, it is conceivable that after a substrate is rinsed, surfaces thereof are re-contaminated with atmospheric components. However, methane plasma treatment is used and therefore a transparent conductive film which is subjected to no rinsing step and which has organic substances adhering thereto is etched such that the organic substances are removed, whereby the transparent conductive film can be surface-rinsed immediately before a photoelectric conversion layer is formed. A chamber for forming the photoelectric conversion layer can be used as a treatment chamber for surface-rinsing the transparent conductive film and therefore the increase in cost due to the capital investment associated with the introduction of an additional apparatus can be suppressed. Furthermore, the use of an H₂ gas and a CH₄ gas, which are commonly used, to form the photoelectric conversion layer provides the effect of suppressing the increase in cost.

The photoelectric conversion layers 2 and 3 can be formed on the clean transparent conductive substrate 1 by methane plasma treatment as described above. It is conceivable that achieving a good interface between the transparent conductive substrate 1 and the photoelectric conversion layer 2 increases the reliability of the photoelectric converter.

In a process not including a step of rinsing a substrate prior to the formation of a photoelectric conversion layer, the surface condition of a transparent conductive substrate depends significantly on an environment prior to the formation of the photoelectric conversion layer and the adhesion between a transparent conductive film and the photoelectric conversion layer is reduced by surface contamination; hence, peeling is likely to occur.

Therefore, in order to evaluate properties of the interface between a transparent conductive film and a photoelectric conversion layer by methane plasma treatment, the following tests were performed in the presence or absence of methane plasma treatment: a test for the adhesion strength between the transparent conductive film and the photoelectric conversion layer and a hot-spot test for a photoelectric converter.

In order to evaluate influences on the interface between a photoelectric conversion layer and a transparent conductive film having a surface cleaned by methane plasma treatment from the viewpoint of reliability, a peel strength test (180 degrees) according to JIS K 6854-2 was performed using the structure of a photoelectric converter module.

The peel strength test (180 degrees) was performed for the solar cell module A, which was prepared in Example 1, and the solar cell module E, which was prepared in Reference Example.

Incidentally, in order to evaluate the adhesion between a transparent conductive film and a semiconductor layer, a lamination step of increasing the adhesion between a sealing resin and a photoelectric conversion layer was performed by treatment at 170° C. or higher for 30 minutes or more.

In the solar cell module E, in which the transparent conductive film was not plasma-treated, peeling occurred between the transparent conductive film and the photoelectric conversion layer at 20 N/cm or more in the peel strength test.

On the other hand, in the solar cell module A, which was subjected to methane plasma treatment, peeling did not occur even at 20 N/cm or more. This shows that the adhesion strength between the transparent conductive substrate 1 and the photoelectric conversion layer 2 was increased by methane plasma treatment.

Next, as a test for the reliability of a photoelectric converter, a hot-spot test (JIS C 8991) was performed for photoelectric converters subjected or not subjected to methane plasma treatment.

Results of the hot-spot test for the photoelectric converters subjected or not subjected to methane plasma treatment are shown in Table 2.

TABLE 2

| | Number of | Faulty |
|---|---|---|
| | peeled pieces | area |
| Solar cell module D (no substrate surface | 99 | Large |
| treatment (Reference Example)) | | |
| Solar cell module A (CH₄ plasma | 56 | Small |
| treatment (Example 1)) | | |

The number of peeled pieces of the solar cell module A, which was subjected to methane plasma treatment under the conditions described in Example 1 is significantly reduced as compared to the solar cell module E, which was not subjected to methane plasma treatment. For hot spots of the solar cell module A, which was subjected to methane plasma treatment, the size and peel area of the hot spots are reduced as compared to the solar cell module E, which was not subjected to methane plasma treatment.

The reduction in number of peeled pieces has the effect of reducing the number of sites causing hot spots by removing fine powder and the like serving as attachment points causing the hot spots by etching because pollutants and the like on surfaces of a substrate are removed by methane plasma treatment.

A photoelectric conversion layer near the sites causing the hot spots is peeled from a transparent conductive film by the thermal expansion caused by the heat generated by a hot spot phenomenon, thereby increasing the peel area. However, the interface between the transparent conductive film and the photoelectric conversion layer is formed well by methane plasma treatment and therefore the expansion of peeling is suppressed by the increase in adhesion therebetween, thereby reducing the peel area. This agrees with the results of the peel strength test.

As described above, a clean substrate surface can be formed by subjecting a transparent conductive film 12 made of SnO₂ to methane plasma treatment even in the case of a surface-contaminated substrate and the increase of properties and reliability of a photoelectric converter could be achieved.

Incidentally, even in the case of subjecting the transparent conductive film 12 made of In₂O₃ or ITO to methane plasma treatment, the transmittance of the transparent conductive film 12 is maintained and the transparent conductive film 12 is surface-cleaned. As a result, the interface between the transparent conductive film 12 and the photoelectric conversion layer 2 is formed well and therefore the adhesion between the transparent conductive film 12 and the photoelectric conversion layer 2 is increased. Thus, the reliability and properties of the photoelectric converter 10 can be enhanced.

In the above, the semiconductor device is a photoelectric converter on a transparent conductive substrate. However, in an embodiment of this invention, a semiconductor device other than the photoelectric converter is effective.

In the above, it has been described that the transparent conductive substrate 1 is brought into the reaction chamber 101 without being rinsed. However, in an embodiment of this invention, the rinsed transparent conductive substrate 1 may be brought into the reaction chamber 101. Even if the rinsed transparent conductive substrate 1 is brought into the reaction chamber 101, the transparent conductive substrate 1 may possibly be surface-contaminated in an environment prior to bringing the transparent conductive substrate 1 into the reaction chamber 101 after rinsing. In such a case, plasma treatment using a CH₄ gas and an H₂ gas is effective.

Furthermore, in the above, it passes through the atmosphere with cleanliness lower than ISO 14644-1 Class 4 and the manufacture of the photoelectric converter is started. Of course, in a class with cleanliness higher than ISO 14644-1 Class 4 or higher, methane plasma treatment is effective in surface-cleaning a substrate before the formation of a semiconductor device.

In Example 1, in the replacement evacuation step, after the substitution gas is introduced into the reaction chamber, the introduction of the substitution gas is stopped when the pressure in the reaction chamber reaches a preset pressure or more, followed by exhausting the substitution gas. However, the pressure need not necessarily be high and the substitution gas may be introduced and exhausted at the same time. Inert gases such as a nitrogen gas, an argon gas, and a helium gas can be used as the substitution gas. A hydrogen gas is used in a subsequent deposition step and therefore is preferred because the influence of containing impurities due to the remaining of the substitution gas is unlikely to appear. Furthermore, the replacement evacuation step may be performed once and is preferably performed several times because the residue in the reaction chamber for methane plasma treatment can be significantly reduced by repeating the replacement evacuation step several times as described in Example. Furthermore, the sufficient evacuation time may be taken instead of the replacement evacuation step (Example 2).

Furthermore, in the above, the treatment chamber for methane plasma and the chamber for forming the photoelectric conversion layer are the same. In an embodiment of this invention, methane plasma treatment and the formation of the photoelectric conversion layer may be performed in different reaction chambers. In this case, the replacement evacuation step may be performed after methane plasma treatment. Methane plasma treatment is effective even in the case of forming the photoelectric conversion layer by a process other than the plasma CVD process.

Furthermore, in the above, it has been described that the photoelectric converter 10 has a structure in which the two photoelectric conversion layers 2 and 3 are stacked on the transparent conductive substrate 1. In an embodiment of this invention, the photoelectric converter 10 is not limited to this structure and may have a structure in which a single photoelectric conversion layer is deposited on the transparent conductive substrate 1 or a structure in which three or more photoelectric conversion layers are stacked on the transparent conductive substrate 1. In general, the photoelectric converter 10 may have a structure in which one or more photoelectric conversion layers are stacked on the transparent conductive substrate 1.

Materials for a p-type semiconductor sub-layer, i-type semiconductor sub-layer, and n-type semiconductor sub-layer forming a single photoelectric conversion layer are not limited to the above-mentioned materials and are generally materials shown in Table 3.

TABLE 3

| P-type semiconductor | I-type semiconductor | N-type semiconductor |
|---|---|---|
| sub-layer | sub-layer | sub-layer |
| P-type a-SiC | I-type a-SiC | N-type a-SiC |
| P-type a-SiN | I-type a-SiN | N-type a-SiN |
| P-type a-SiO | I-type a-SiO | N-type a-SiO |
| P-type a-Si | I-type a-Si | N-type a-Si |
| P-type a-SiGe | I-type a-SiGe | N-type a-SiGe |
| P-type a-Ge | I-type a-Ge | N-type a-Ge |
| P-type μc-SiC | I-type μc-SiC | N-type μc-SiC |
| P-type μc-SiN | I-type μc-SiN | N-type μc-SiN |
| P-type μc-SiO | I-type μc-SiO | N-type μc-SiO |
| P-type μc-Si | I-type μc-Si | N-type μc-Si |
| P-type μc-SiGe | I-type μc-SiGe | N-type μc-SiGe |
| P-type μc-Ge | I-type μc-Ge | N-type μc-Ge |

A photoelectric conversion layer is not limited to a silicon semiconductor material and may be made of a compound semiconductor layer such as CdTe or CIGS. In general, the photoelectric conversion layer may be made of any material having photoelectric conversion properties.

When the photoelectric converter 10 includes a single photoelectric conversion layer, each of a p-type semiconductor sub-layer, i-type semiconductor sub-layer, and n-type semiconductor sub-layer forming the single photoelectric conversion layer is made of one selected from the materials shown in Table 3. The i-type semiconductor sub-layer is preferably made of a material having an optical band gap less than the optical band gap of the p-type semiconductor sub-layer.

When the photoelectric converter 10 includes two or more photoelectric conversion layers, two or more i-type semiconductor sub-layers included in the two or more photoelectric conversion layers are made of materials with optical band gaps decreasing from the transparent conductive film 12 toward the back electrode 4.

The materials shown in Table 3 are formed by a plasma CVD process. Therefore, when the photoelectric converter 10 includes one or more photoelectric conversion layers, the photoelectric converter 10 is manufactured using the plasma apparatus 100 in accordance with Steps (a) to (e) shown in FIG. 7. In this case, when the number of the photoelectric conversion layers is one, Step (d) is omitted. When the number of the photoelectric conversion layers is two or more, a step of depositing a p-type semiconductor sub-layer, an i-type semiconductor sub-layer, and an n-type semiconductor sub-layer by the plasma CVD process in that order is repeated between Steps (b) and (e) twice or more.

The embodiments disclosed herein are for exemplification and should not in any way be construed as limitative. The scope of the present invention is defined by the claims rather than the description of the above embodiments and is intended to include all modifications within the sense and scope equivalent to the claims.

### INDUSTRIAL APPLICABILITY

This invention is applied to a method for manufacturing a semiconductor device.

1. A method for manufacturing a semiconductor device, comprising:
a first step in which in a transparent conductive substrate in which a transparent conductive film mainly containing tin oxide or indium oxide is placed on a light-transmissive base plate, a surface of the transparent conductive film is plasma-treated using a CH₄ gas and an H₂ gas; and
a second step of fabricating a semiconductor device on the transparent conductive film after the first step.

2. The method for manufacturing the semiconductor device according to claim 1, further comprising a third step of introducing a substitution gas into a reaction chamber in which the first step is performed and exhausting the substitution gas, the third step being performed between the first step and the second step.

3. The method for manufacturing the semiconductor device according to claim 1, wherein the semiconductor device is a photoelectric converter.

4. The method for manufacturing the semiconductor device according to claim 1, wherein in the first step, the gas flow rate ratio that is the ratio of the flow rate of the CH₄ gas to the sum of the flow rate of the CH₄ gas and the flow rate of the H₂ gas is 0.1 or more and 0.9 or less.

5. The method for manufacturing the semiconductor device according to claim 1, wherein in the first step, the gas flow rate ratio that is the ratio of the flow rate of the CH₄ gas to the sum of the flow rate of the CH₄ gas and the flow rate of the H₂ gas is 0.1 or more and 0.7 or less.

6. The method for manufacturing the semiconductor device according to claim 1, wherein in the first step, the substrate temperature during plasma treatment is 200° C. or lower.

7. The method for manufacturing the semiconductor device according to claim 1, wherein the first step is performed without rinsing the transparent conductive substrate.

8. The method for manufacturing the semiconductor device according to claim 1, wherein the transparent conductive substrate passes through an atmosphere with cleanliness lower than ISO 14644-1 Class 4 and is brought into the reaction chamber in which the first step is performed.

9. The method for manufacturing the semiconductor device according to claim 1, wherein the first and second steps are performed in the same reaction chamber.
